(19) United States
(12) Patent Application Publication
(10) Pub. No.: US 2021/0384395 A1
(43) Pub. Date: Dec. 9, 2021

(54) Radiation-Emitting Component

(71) Applicant: OSRAM Opto Semiconductors GmbH, Regensburg (DE)

(72) Inventors: Norwin von Malm, Nittendorf (DE); Reinhard Streitel, Laaber (DE); Kathy Schmidtke, Obertraubling (DE)

(21) Appl. No.: 17/415,977

(22) PCT Filed: Dec. 16, 2019
(86) PCT No.: PCT/EP2019/085330

§ 371 Date: Jun. 18, 2021

(30) Foreign Application Priority Data
Dec. 19, 2018 (DE) 10 2018 132 955.5

(51) Int. Cl. H01L 33/62; H01L 33/64; H01L 33/46

(52) U.S. Cl. CPC H01L 33/62; H01L 2933/0075; H01L 33/46; H01L 33/641

(57) ABSTRACT

A radiation-emitting component is disclosed. In an embodiment a radiation-emitting component includes a radiation-emitting semiconductor chip and a transparent joining layer mechanically stably connecting the radiation-emitting semiconductor chip with a carrier, wherein the transparent joining layer comprises a matrix material in which a plurality of nanoparticles are located.

This patent application is a national phase filing under section 371 of PCT/EP2019/085330, filed Dec. 16, 2019, which claims the priority of German patent application 102018132955.5, filed Dec. 19, 2018, each of which is incorporated herein by reference in its entirety.

### TECHNICAL FIELD

The disclosure relates to a radiation-emitting component.

### Background

A radiation-emitting component is specified, for example, in U.S. Pat. No. 9,722,159 B2.

### SUMMARY

Embodiments provide a radiation-emitting component with improved heat management.

According to one embodiment, the radiation-emitting component comprises a radiation-emitting semiconductor chip. During operation, the radiation-emitting semiconductor chip emits electromagnetic radiation from a radiation emitting surface. For example, the radiation-emitting semiconductor chip emits ultraviolet light, visible light, and/or infrared light during operation.

According to another embodiment, the radiation-emitting component comprises a transparent joining layer. The transparent joining layer connects the radiation-emitting semiconductor chip to a carrier in a mechanically stable manner. The term “transparent” is used here and hereinafter particularly preferably to refer to an element that transmits at least 85%, preferably at least 90%, of the electromagnetic radiation of the radiation-emitting semiconductor chip.

According to another embodiment of the radiation-emitting component, the transparent joining layer connects the radiation-emitting semiconductor chip to the carrier in a mechanically stable manner. Particularly preferably, the transparent joining layer connects the radiation-emitting semiconductor chip to the carrier in a materially cohesive manner. Preferably, the transparent joining layer is in direct contact over its entire surface with a mounting surface of the semiconductor chip, which is provided for mounting the semiconductor chip on the carrier.

According to a particularly preferred embodiment of the radiation-emitting component, the transparent joining layer comprises a matrix material in which a plurality of nanoparticles are brought in. In other words, the transparent joining layer comprises the matrix material and the plurality of nanoparticles or is formed from the matrix material and the plurality of nanoparticles. Advantageously, with the aid of the nanoparticles, it is possible to significantly increase the thermal conductivity of the joining layer compared to a conventional joining layer without nanoparticles. This results in particularly good thermal bonding of the radiation-emitting semiconductor chip to the carrier. Furthermore, the nanoparticles do not or only slightly impair the optical transparency of the joining layer, so that the transparent joining layer comprising the matrix material and the nanoparticles transmits at least 85%, preferably 90%, of the electromagnetic radiation of the radiation-emitting semiconductor chip.

A concentration of the nanoparticles in the matrix material is preferably adjusted so that the thermal conductivity of the joining layer is as high as possible, but the necessary adhesion between the mounting surface of the semiconductor chip and the carrier is still given. For example, the concentration of nanoparticles in the matrix material comprises a value between 35 wt % inclusive and 85 wt % inclusive, preferably between 35 wt % inclusive and 65 wt % inclusive.

According to another embodiment of the radiation-emitting component, the nanoparticles comprise a diameter between 1 nanometer inclusive and 100 nanometers inclusive. Particularly preferably, the nanoparticles comprise a diameter between 2 nanometers inclusive and 30 nanometers inclusive. Compared to particles with diameters in the micrometer range, such small nanoparticles comprise the advantage of not or only very slightly impairing the transparency of the joining layer, at least for electromagnetic radiation of the radiation-emitting semiconductor chip.

According to another preferred embodiment of the radiation-emitting component, a thickness of the joining layer is not greater than 2 micrometers. Preferably, the thickness of the joining layer is not greater than 1 micrometer and particularly preferably not greater than 300 nanometers. The joining layer also particularly preferably comprises a comparatively homogeneous thickness which does not deviate by more than 5% from the stated preferred value. In particular, the addition of the nanoparticles to the matrix material makes it advantageously possible to form a very thin joining layer compared with the addition of particles with diameters in the micrometer range, since the dimensions of the nanoparticles limit the minimum achievable thickness of the joining layer.

With a comparatively small thickness of the joining layer, a particularly good thermal connection of the radiation-emitting semiconductor chip to the carrier can be achieved with advantage. In this way, heat generated in the radiation-emitting semiconductor chip during operation is transported away particularly well via the joining layer to the carrier.

Preferably, a thermal conductivity of the joining layer is at least 1 W/mK. Particularly preferably, the joining layer comprises a thermal conductivity of at least 3 W/mK. According to another embodiment of the radiation emitting device, the joining layer comprises a thermal conductivity between 1 W/mK inclusive and 3 W/mK inclusive.

According to another embodiment of the radiation-emitting component, the nanoparticles comprise a coating. Preferably, the coating is applied to a core of each nanoparticle. Particularly preferably, each nanoparticle is formed of a core and a coating applied to the core, preferably over the entire surface. The coating is particularly preferred to at least reduce agglomeration of the nanoparticles in the matrix material. Due to their small size, surface effects have a greater influence on nanoparticles than it is the case with larger particles. Therefore, nanoparticles agglomerate particularly easily in a surrounding medium, such as the matrix material, if their surface properties allow only comparatively poor wetting with the surrounding medium. Preferably, the coating alters the wettability of the nanoparticles with the matrix material by matching the surface properties of the nanoparticles to the surface properties of the matrix. With other words, the nanoparticles are preferably functionalized by the coating in such a way that they distribute particularly well in the matrix material of the joining layer.

The coating can have an inorganic or organic character. For example, the coating comprises a silanol, an acrylate or SiO₂ or consists of one of these materials.

Particularly preferably, the cores of the nanoparticles comprise a material with a particularly high thermal conductivity. Preferably, the material of the cores of the nanoparticles is an inorganic material. For example, the nanoparticles and/or their cores comprise a material selected from the following group: diamond, Si₃N₄, AlN, Al₂O₃, SiC, ZrO₂, BN, HfO₂, ZnO, GaP, MgF₂.

According to another embodiment of the radiation-emitting component, the matrix material comprises or is formed from a polymer. For example, the matrix material comprises or is formed from one of the following materials: polysiloxane, epoxy, acrylate. Further, it is also possible that the matrix material comprises or is formed from a mixture of at least two of these materials.

For example, the matrix material comprises a polysiloxane that is cured by hydrosilylation. The hydrosilylation can be thermally or optically activated in this case.

The material of the nanoparticles can be selected such that their refractive index essentially corresponds to the refractive index of the matrix material. In this way, internal reflections within the joining layer are at least reduced.

Furthermore, it is also possible that the refractive index of the nanoparticles is specifically selected to be larger or smaller than that of the matrix material in order to impart at least partially diffuse reflective properties to the joining layer.

If the nanoparticles comprise a coating, a material of the cores of the nanoparticles and a material of the coating may be selected such that their overall refractive index, i.e., the refractive index of the nanoparticle comprising the core and the coating, is substantially equal to the refractive index of the matrix material. In this case, it is also possible that the overall refractive index of the nanoparticles is selectively set to be greater than or less than that of the matrix material in order to impart at least partially diffuse reflective properties to the joining layer.

According to another embodiment of the radiation-emitting component, the radiation-emitting semiconductor chip comprises an epitaxial semiconductor layer sequence with an active zone. The active zone is capable to generate, during operation, the electromagnetic radiation emitted from the radiation emitting surface of the semiconductor chip.

The active zone preferably comprises a pn junction, a double heterostructure, a single quantum well structure or, particularly preferably, a multiple quantum well (MQW) structure for radiation generation. The term quantum well structure here does not imply any indication of the dimensionality of the quantization. It thus includes inter alia quantum wells, quantum wires and quantum dots and any combination of these structures.

According to another embodiment of the radiation-emitting component, the epitaxial semiconductor layer sequence is based on or formed from a nitride compound semiconductor material. Nitride compound semiconductor materials are compound semiconductor materials containing nitrogen, such as the materials from the system InₓAl_{y}Ga_{1-x-y}N with 0≤x≤1, 0≤y≤1 and x+y≤1. The active zone of an epitaxial semiconductor layer sequence based on a nitride compound semiconductor material or formed from a nitride compound semiconductor material generally generates ultraviolet to blue light.

According to another embodiment of the radiation emitting device, the epitaxial semiconductor layer sequence is based on or formed from a phosphide compound semiconductor material. Phosphide compound semiconductor materials are compound semiconductor materials containing phosphorus, such as the materials from the system InₓAl_{y}Ga_{1-x-y}P with 0≤x≤1, 0≤y≤1 and x+y≤1. The active zone of an epitaxial semiconductor layer sequence based on a nitride compound semiconductor material or formed from a nitride compound semiconductor material generally generates light from the green to red spectral range.

Furthermore, it is also possible that the epitaxial semiconductor layer sequence is based on or formed from an arsenide compound semiconductor material. Arsenide compound semiconductor materials are compound semiconductor materials containing arsenic, such as the materials from the system InₓAl_{y}Ga_{1-x-y}As with 0≤x≤1, 0≤y≤1 and x+y≤1. The active zone of an epitaxial semiconductor layer sequence based on an arsenide compound semiconductor material or formed from an arsenide compound semiconductor material generally generates light from the red to infrared spectral range.

According to a further embodiment of the radiation-emitting component, the epitaxial semiconductor layer sequence is arranged on a carrier element. The carrier element is preferably transparent for electromagnetic radiation of the active zone, in particular for electromagnetic radiation of the first wavelength range.

The epitaxial semiconductor layer sequence may be epitaxially grown on the carrier element. With other words, the carrier element may be a growth substrate for the epitaxial semiconductor layer sequence. Furthermore, it is also possible that the epitaxial semiconductor layer sequence is epitaxially grown separately from the carrier element on a growth substrate and then transferred to the carrier element. Such semiconductor chips are also referred to as thin film semiconductor chips. Thin film semiconductor chips generally emit electromagnetic radiation generated in the active zone predominantly through a main surface opposite to the mounting surface. With other words, the radiation emitting surface of thin film semiconductor chips is usually substantially formed by the main surface opposite to the mounting surface. Thin film semiconductor chips generally comprise a predominantly Lambertian radiation characteristic.

According to another embodiment of the radiation-emitting component, a reflective layer is arranged between the epitaxial semiconductor layer sequence and the carrier element. The reflective layer may be, for example, a distributed Bragg reflector (DBR) or a metal layer. The reflective layer particularly preferably directs electromagnetic radiation generated in the active zone of the epitaxial semiconductor layer sequence and emitted to a mounting surface of the semiconductor chip to the radiation exit surface. In this manner, the light extraction from the radiation-emitting component can be increased. In this embodiment, the carrier element is generally not a growth substrate for the epitaxial semiconductor layer sequence. Rather, the epitaxial semiconductor layer sequence is generally epitaxially deposited on a separate growth substrate and then transferred to the carrier element.

Particularly preferably, the radiation-emitting semiconductor chip is a volume-emitting semiconductor chip.

A volume-emitting semiconductor chip comprises a carrier element on which the semiconductor layer sequence has been epitaxially grown or to which the epitaxial semiconductor layer sequence has been transferred. The carrier element is particularly preferably transparent to electromagnetic radiation generated in the active zone. For example, the carrier element comprises or is made of one of the following materials: sapphire, silicon carbide, or glass. In this context, sapphire and silicon carbide are generally suitable as growth substrates for epitaxial semiconductor layer sequences based on a nitride compound semiconductor material.

Volume-emitting semiconductor chips usually emit the electromagnetic radiation generated in the active zone not only via the main surface opposite the mounting surface, but also via side surfaces arranged between the mounting surface and the main surface. In this regard, the side surfaces of the radiation-emitting semiconductor chip are generally formed substantially by side surfaces of the carrier element. With other words, the radiation emitting surface of a volume-emitting semiconductor chip comprises at least a part of the side surfaces in addition to the main surface opposite to the mounting surface.

Particularly preferably, the volume-emitting semiconductor chip comprises two electrical contacts on the main surface opposite to the mounting surface. The electrical contacts serve to electrically contact the semiconductor chip in the radiation-emitting component. For example, the electrical contacts are electrically conductively connected with bonding wires to electrical connection pads encompassed by the carrier.

According to a particularly preferred embodiment of the radiation-emitting component, the epitaxial semiconductor layer sequence comprises or is formed of a nitride compound semiconductor material, while the carrier element comprises or is formed of sapphire. Particularly preferably, in this embodiment, the epitaxial semiconductor layer sequence is epitaxially grown on the carrier element. Generally, such a semiconductor chip is a volume-emitting semiconductor chip that emits light from the blue to ultraviolet spectral range.

According to another particularly preferred embodiment of the radiation-emitting component, the epitaxial semiconductor layer sequence is based on a phosphide compound semiconductor material or on an arsenide compound semiconductor material or consists of one of these two materials. In this embodiment, the carrier element particularly preferably comprises glass or consists of glass. Typically, such a semiconductor chip is a volume-emitting semiconductor chip that emits light from the green to red spectral range.

According to one embodiment of the radiation-emitting component, the carrier is a leadframe. The leadframe preferably comprises a surface formed at least in part by a metallic layer. The metallic layer preferably comprises or consists of silver, gold, alloys with silver, or alloys with gold. The joining layer described herein is particularly suitable for imparting a particularly good adhesion between the mounting surface of the radiation-emitting semiconductor chip and a silver-containing or gold-containing surface, even with a comparatively small thickness of the joining layer.

For example, a core element of the leadframe to which the coating is applied may be formed of or comprise copper. It is possible for the leadframe to be overmolded by a housing body. In this case, the leadframe forms part of a housing.

The radiation emitting device is based, inter alia, on the idea of bringing in nanoparticles into the joining layer, which preferably comprise an inorganic highly thermally conductive material. Due to their small size, it is advantageously possible to make the joining layer comparatively thin, so that good overall thermal bonding of the semiconductor chip to the carrier is achieved.

In addition, due to their small size, nanoparticles generally do not or only slightly impair the optical transparency of the joining layer, compared to larger particles. In particular, a transparent joining layer is of great advantage in connection with volume-emitting semiconductor chips, since in the case of volume-emitting semiconductor chips electromagnetic radiation of the active zone passes through the carrier element and the mounting surface of the semiconductor chip to the joining layer. If the joining layer comprises a high permeability for electromagnetic radiation of the active zone, electromagnetic radiation passing through the joining layer can be reflected with advantage by the metallic layer of the leadframe.

Furthermore, it is presently proposed with advantage to functionalize the nanoparticles with a coating which particularly preferably at least reduces agglomeration of the nanoparticles in the matrix material. Preferably, no more than 10% and particularly preferably no more than 5% of the nanoparticles in the matrix material are agglomerated into larger particles. This further contributes to the optical transparency of the joining layer.

### BRIEF DESCRIPTION OF THE DRAWINGS

Further advantageous embodiments and further embodiments of the invention result from the exemplary embodiments described below in combination with the figures.

FIG. 1 shows a schematic sectional view of a radiation-emitting component according to an exemplary embodiment;

FIGS. 2 and 3 each show an embodiment of the circular section marked in FIG. 1; and

FIG. 4 shows a schematic sectional view of a radiation-emitting component according to a further exemplary embodiment.

### DETAILED DESCRIPTION OF ILLUSTRATIVE EMBODIMENTS

Elements that are identical, of the same type or have the same effect are marked in the figures with the same reference signs. The figures and the proportions of the elements shown in the figures with respect to one another are not to be regarded as to scale. Rather, individual elements, in particular layer thicknesses, may be shown exaggeratedly large for better representability and/or understanding.

The radiation-emitting device according to the exemplary embodiment of FIG. 1 comprises a radiation-emitting semiconductor chip 1. The radiation-emitting semiconductor chip 1 is applied to a carrier 4 via a mounting surface 2 with a transparent joining layer 3 in a mechanically stable and materially cohesive manner.

The radiation-emitting semiconductor chip 1 comprises an epitaxial semiconductor layer sequence 5 with an active zone 6. The epitaxial semiconductor layer sequence 5 is presently formed of a nitride compound semiconductor material. The active zone 6 is adapted to generate visible blue light.

The radiation emitting semiconductor chip 1 further comprises presently a carrier element 7 which is transparent to the electromagnetic radiation generated in the active zone 6 of the epitaxial semiconductor layer sequence 5.

In the present exemplary embodiment, the carrier element 7 is formed of sapphire. The epitaxial semiconductor layer sequence 5 is epitaxially grown on the carrier element 7.

Alternatively, it is also possible that the epitaxial semiconductor layer sequence 5 is based on a phosphide compound semiconductor material or an arsenide compound semiconductor material or is formed from one of these materials. In this case, the epitaxial semiconductor layer sequence 5 may be applied to a carrier element 7 which comprises glass or is made of glass. In this embodiment, the epitaxial semiconductor layer sequence 5 is generally epitaxially grown on a substrate other than the carrier element 7, for example, on a substrate comprising or formed of a semiconductor material.

In the present case, the radiation-emitting semiconductor chip 1 is a volume-emitting semiconductor chip 1 that emits electromagnetic radiation generated in the active zone 6 not via a main surface 8 facing the mounting surface 2, but also via side surfaces of the carrier element 7. In addition, the radiation-emitting semiconductor chip 1 comprises two electrical contacts 9 on the main surface 8 opposite the mounting surface 2. The electrical contacts 9 are used for electrically contacting the radiation-emitting semiconductor chip 1. For example, the electrical contacts 9 can be electrically conductively connected to electrical connection pads of the carrier 4 with bonding wires (not shown).

In the present case, the joining layer 3 comprises a matrix material 10 in which a plurality of nanoparticles 11 are brought in. The nanoparticles 11 increase the thermal conductivity of the joining layer 3 with advantage compared to a joining layer made of a pure matrix material 10. The matrix material 10 comprises, for example, a polymer such as a polysiloxane, an epoxy and/or an acrylate.

The nanoparticles 11 have a concentration in the matrix material 10 between, inclusive 0.35 wt % and 85 wt % inclusive, preferably between inclusive 0.35 wt % and 65 wt %, inclusive.

Preferably, the nanoparticles 11 comprise a core 12 and a coating 13. The core 12 of the nanoparticles 11 is presently formed from an inorganic material. For example, the cores 12 of the nanoparticles 11 are formed from one of the following materials: Diamond, Si₃N₄, AlN, Al₂O₃, SiC, ZrO₂, BN, HfO₂, ZnO, GaP, MgF₂. The coating 13 is applied to the cores 12, preferably over the entire surface. Preferably, the coating 13 functionalizes the nanoparticles 11 in such a way that their agglomeration in the matrix material 10 is at least largely prevented. Preferably, the nanoparticles 11 comprise a diameter not greater than 100 nanometers.

In the radiation-emitting component of the present exemplary embodiment, the joining layer 3 comprises a comparatively small thickness D. In the present case, the thickness D of the joining layer 3 does not exceed a value of 300 nanometers.

At the side surfaces of the radiation-emitting semiconductor chip 1, the material of the joining layer 3 forms a fillet 14. The fillet 14 may completely surround the radiation-emitting semiconductor chip 1. The fillet 14 is generally formed when the radiation-emitting semiconductor chip 1 is joined to the carrier 4. During joining, the radiation-emitting semiconductor chip 1 is generally pressed onto a drop of a liquid joining material arranged on the carrier 4. When the radiation-emitting semiconductor chip 1 is pressed onto the carrier 4, a layer of the liquid joining material is formed between the radiation-emitting semiconductor chip 1 and the carrier 4. In addition, it is possible for liquid joining material to exit laterally and form the fillet 14 on the side surfaces of the radiation emitting semiconductor chip 1.

The liquid joining material generally comprises the matrix material 10 in liquid form, in which the nanoparticles 11 are brought in. The joining layer 3 is created from the liquid joining material by curing the liquid matrix material. For example, the matrix material 10 comprises a polysiloxane that is cured by hydrosilylation. The hydrosilylation can be activated thermally or optically in this case.

The carrier 4 to which the radiation-emitting semiconductor chip 1 is applied is presently a leadframe. The leadframe comprises presently a core element which comprises copper or is formed from copper. The core element is provided over its entire surface with a metallic layer 15, which forms a surface of the leadframe. The metallic layer 15 comprises, for example, gold and/or silver or an alloy with silver and/or gold. Furthermore, it is also possible that the metallic layer 15 consists of one of these materials.

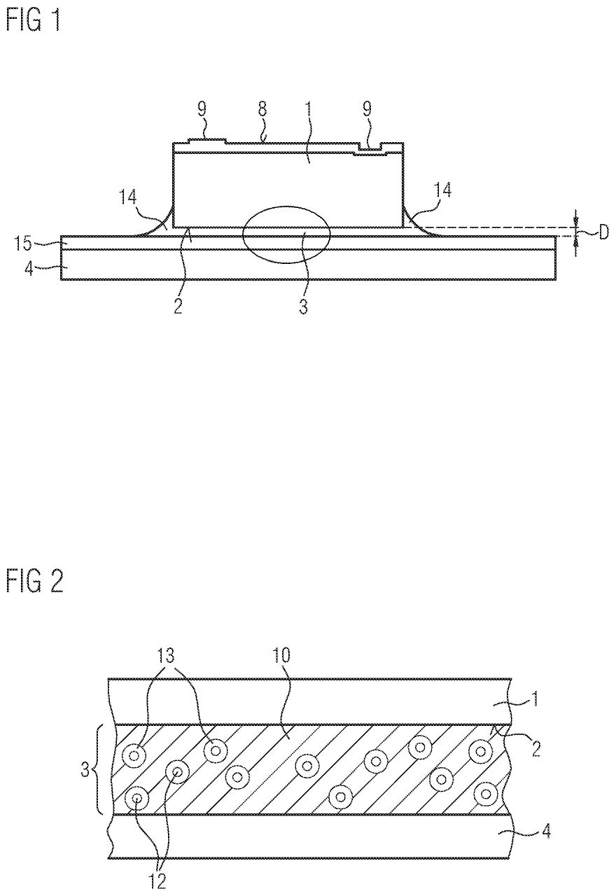

The section of the radiation-emitting component marked with a circle in FIG. 1 is shown in more detail in FIG. 2. FIG. 2 shows in particular a section of the joining layer 3 between the mounting surface 2 of the radiation-emitting semiconductor chip 1 and the metallic layer 15 of the carrier 4. The joining layer 3 is here particularly preferably transparent to electromagnetic radiation generated in the active zone 6 of the radiation-emitting semiconductor chip 1. The nanoparticles 11 in the matrix material 10 of the joining layer 3 advantageously increase the thermal conductivity of the joining layer 3, but do not or only slightly impair the optical transparency of the joining layer 3 for electromagnetic radiation of the active zone.

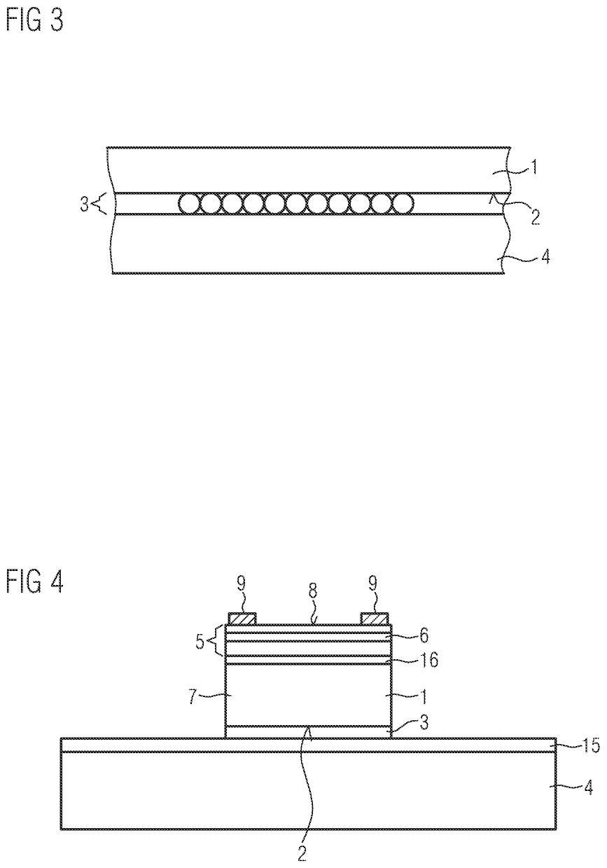

FIG. 3 shows another representation of the section of the radiation-emitting component in FIG. 1 marked with a circle. FIG. 3 shows schematically that the nanoparticles 11 in the joining layer 3 can also be arranged in only one monolayer. Due to the small diameter of the nanoparticles 11, the joining layer 3 can advantageously be made particularly thin. Particularly preferably, the joining layer 3 comprises a thickness not exceeding 300 nanometers.

The radiation-emitting component according to the exemplary embodiment of FIG. 4 comprises a radiation-emitting semiconductor chip 1 with an epitaxial semiconductor layer sequence 5 which is based on a phosphide compound semiconductor material or on an arsenide compound semiconductor material or is formed from one of these materials. The active zone 6 of an epitaxial semiconductor layer sequence based on a phosphide compound semiconductor material generally generates electromagnetic radiation from the green to red spectral range, while an epitaxial semiconductor layer sequence based on an arsenide compound semiconductor material generally generates electromagnetic radiation from the red to infrared spectral range.

In the present exemplary embodiment, the epitaxial semiconductor layer sequence 5 is applied to a carrier element 7 formed of glass. A reflective layer 16 is presently arranged between the epitaxial semiconductor layer sequence 5 and the carrier element 7 to direct electromagnetic radiation generated in the active zone 6 to a main surface 8 of the semiconductor chip 1, which opposites a mounting surface 2 of the radiation-emitting semiconductor chip 1. Furthermore, the mounting surface 2 of the radiation-emitting semiconductor chip 1 is bonded with a joining layer 3 to a carrier 4 in a materially cohesive and mechanically stable manner.

The joining layer 3 comprises presently a polymer as matrix material 10, such as a polysiloxane, an acrylate or an epoxy. A plurality of nanoparticles 11 are brought into the matrix material 10. The nanoparticles 11 comprise a core 12 made of an inorganic material that has a particularly high thermal conductivity. Suitable materials for the cores 12 have already been mentioned in the general part of the description. The nanoparticles 11 increase the thermal conductivity of the joining layer 3 with advantage compared to a joining layer made of a pure matrix material 10.

A coating 13 is presently applied to the cores 12 of the nanoparticles 11, which functionalizes the nanoparticles 11 in such a way that they distribute particularly well in the matrix material 10. The coating 13 advantageously reduces agglomeration of the nanoparticles 11 in the matrix material 10, at least to a large extent.

The nanoparticles 11 comprise a concentration in the matrix material 10 which sets the thermal conductivity of the joining layer 3 to a particularly high level, but at the same time enables good adhesion between the mounting surface 2 of the radiation-emitting semiconductor chip 1 and the surface of the carrier 4.

The joining layer 3 comprises a comparatively small thickness D in the radiation emitting device of the present exemplary embodiment. In the present application, the thickness D of the joining layer 3 does not exceed a value of 1 micrometer.

The invention is not limited to the exemplary embodiments by the description thereof. Rather, the invention encompasses any new feature as well as any combination of features, which in particular includes any combination of features in the patent claims, even if that feature or combination itself is not explicitly specified in the patent claims or exemplary embodiments.

1.-17. (canceled)

18. A radiation-emitting component comprising:
a radiation-emitting semiconductor chip; and
a transparent joining layer mechanically stably connecting the radiation-emitting semiconductor chip with a carrier,
wherein the transparent joining layer comprises a matrix material in which a plurality of nanoparticles are located.

19. The radiation-emitting component according to claim 18, wherein the nanoparticles comprise a diameter between 1 nanometer and 100 nanometers, inclusive.

20. The radiation-emitting component according to claim 18, wherein the nanoparticles comprise a diameter between 2 nanometers and 30 nanometers, inclusive.

21. The radiation-emitting component according to claim 18, wherein a thickness of the joining layer is not greater than 2 micrometers.

22. The radiation-emitting component according to claim 18, wherein a thickness of the joining layer is not greater than 1 micrometer.

23. The radiation-emitting component according to claim 18, wherein the joining layer comprises a thermal conductivity of at least 1 W/mK.

24. The radiation-emitting component according to claim 18, wherein the joining layer comprises a thermal conductivity of at least 3 W/mK.

25. The radiation-emitting component according to claim 18, wherein cores of the nanoparticles comprise a material selected from the group consisting of diamond, Si₃N₄, AlN, Al₂O₃, SiC, ZrO₂, BN, HfO₂, ZnO, GaP, and MgF₂.

26. The radiation-emitting component according to claim 18, wherein the matrix material comprises polysiloxane, epoxy or acrylate.

27. The radiation-emitting component according to claim 26, wherein the matrix material comprises a polysiloxane cured by hydrosilylation which is thermally or optically activated.

28. The radiation-emitting component according to claim i8, wherein the nanoparticles comprise a coating at least reducing agglomeration of the nanoparticles in the matrix material.

29. The radiation-emitting component according to claim 28, wherein the coating comprises a silanol, an acrylate or SiO₂.

30. The radiation-emitting component according to claim i8,
wherein the radiation-emitting semiconductor chip comprises an epitaxial semiconductor layer sequence with an active zone,
wherein the active zone is configured to generate electromagnetic radiation emitted from a radiation-emitting surface of the semiconductor chip, and
wherein the epitaxial semiconductor layer sequence is arrnaged on a carrier element which is transparent to electromagnetic radiation from the active zone.

31. The radiation-emitting component according to claim 30, wherein the epitaxial semiconductor layer sequence is based on a nitride compound semiconductor material and the carrier element comprises sapphire.

32. The radiation-emitting component according to claim 30, wherein the epitaxial semiconductor layer sequence is comprised of a phosphide compound semiconductor material or an arsenide compound semiconductor material and the carrier element comprises glass.

33. The radiation-emitting component according to claim 32, wherein a reflective layer is arranged between the epitaxial semiconductor layer sequence and the carrier element.

34. The radiation-emitting component according to claim 18, wherein the carrier is a leadframe, a surface of which is at least partially formed by a metallic layer comprising silver, gold, alloys with gold, or alloys with silver.

35. A radiation-emitting component comprising:
radiation-emitting semiconductor chip; and
a transparent joining layer mechanically stably connecting the radiation-emitting semiconductor chip with a carrier,
wherein the transparent joining layer comprises a matrix material in which a plurality of nanoparticles are located, and
wherein a thickness of the joining layer is not greater than 300 nanometers.
